(19) United States
(12) Patent Application Publication
(10) Pub. No.: US 2024/0143883 A1
(43) Pub. Date: May 2, 2024

(54) LAYOUT METHOD AND APPLICATION OF SCALABLE MULTI-DIE NETWORK-ON-CHIP FPGA ARCHITECTURE

(71) Applicant: SHANGHAITECH UNIVERSITY, Shanghai (CN)

(72) Inventors: Jianwen LUO, Shanghai (CN); Yajun HA, Shanghai (CN)

(73) Assignee: SHANGHAITECH UNIVERSITY, Shanghai (CN)

(21) Appl. No.: 18/203,662

(22) Filed: May 31, 2023

Related U.S. Application Data
(63) Continuation of application No. PCT/CN2022/134243, filed on Dec. 25, 2022.

(30) Foreign Application Priority Data
Oct. 14, 2022 (CN) 202211257475.X

(51) Int. Cl. G06F 30/347; G06F 30/31

(52) U.S. Cl. CPC G06F 30/347; G06F 30/31

(57) ABSTRACT

A layout method for a scalable multi-die network-on-chip FPGA architecture is provided. An application of the aforementioned layout method for the scalable multi-die network-on-chip FPGA architecture is further provided. A scalable multi-die FPGA architecture based on network-on-chip and a corresponding hierarchical recursive layout algorithm are provided, aiming to directly map a register transfer level dataflow design generated by existing high-level synthesis onto the provided interconnection architecture. The layout method can exploit the potential for hierarchical topology and make more efficient use of dedicated interconnection resources, such as cross-die nets, network-on-chips, and high-speed transceivers.

### CROSS REFERENCE TO THE RELATED APPLICATIONS

This application is the continuation application of International Application No. PCT/CN2022/134243, filed on Nov. 25, 2022, which is based upon and claims priority to Chinese Patent Application No. 202211257475.X, filed on Oct. 14, 2022, the entire contents of which are incorporated herein by reference.

### TECHNICAL FIELD

The present disclosure relates to a layout method for a scalable multi-die network-on-chip field-programmable gate array (FPGA) architecture and an application thereof.

### BACKGROUND

Emerging applications typified by a Convolution Network Accelerator [1] and a Deep Learning Accelerator [2] require larger multi-die FPGA. However, the scalability of previously existing architectures and associated electronic design automation (EDA) tools may not meet the requirement for a growing number of FPGA die. In recent years, many efforts have been made for innovations in interconnect architectures. For example, [3] and [4] show methods to improve system performance using network-on-chips.

These architectural innovations place new requirements on an EDA tool. To address these challenges, [5] provides a high-performance custom interconnect architecture for FPGA with HBM and a novel optimization technique based on high-level comprehensive to improve the performance of AXI network-on-chip components. However, these methods only consider the FPGA of traditional substrate-based mesh topologies and cannot map designs onto more complex die topologies. After observing the traditional interconnect architecture on a modern substrate-based multi-die FPGA architecture, [6] spreads the submodules in the design across multiple dies to improve the overall performance of the system. However, this method only focuses on the traditional interconnection resources and ignores the dedicated interconnection resources represented by the network-on-chip. These existing systems can only handle traditional substrate-based architectures, which do not include scalable multi-die FPGA architectures.

Reference document:

[1] W. Jiang, H. Yu, X. Liu, and Y. Ha, “Energy efficiency optimization of fpga-based CNN accelerators with full data reuse and VFS,” in 26^{th} IEEE International Conference on Electronics, Circuits and Systems, ICECS 2019, Genoa, Italy, November 27-29, 2019. IEEE, 2019, pp.446-449.

[2] W. Jiang, H. Yu, X. Liu, H. Sun, R. Li, and Y. Ha, “Tait: One-shot full integer light weight dnn quantization via tunable activation imbalance transfer,” in 2021 58th ACM/IEEE Design Automation Conference (DAC). IEEE, 2021, pp. 1027-1032.

[3] K. Khalil, O. Eldash, B. Dey, A. Kumar, and M. Bayoumi, “An efficient embryonic hardware architecture based on network-on-chip,” in2021 IEEE International Midwest Symposium on Circuits and Systems (MWSCAS), 2021, pp. 449-452.

[4] G. Passas, M. Katevenis, and D. Pnevmatikatos, “Crossbar nocs are scalable beyond 100 nodes,” Trans. Comp.-Aided Des. Integ. Cir. Sys., vol. 31, no. 4, p. 573-585, Apr. 2012.

[5] Y. -k. Choi, Y. Chi, W. Qiao, N. Samardzic, and J. Cong, “Hbm connect: High-performance hls interconnect for fpga hbm,” in The2021 ACM/SIGDA International Symposium on Field-Programmable Gate Arrays, ser. FPGA '21. New York, NY, USA: Association for Computing Machinery, 2021, p. 116-126.

[6] L. Guo, Y. Chi, J. Wang, J. Lau, W. Qiao, E. Ustun, Z. Zhang, and J. Cong, “Autobridge: Coupling coarse-grained floorplanning and pipelining for high-frequency hls design on multi-die fpgas,” in The2021 ACM/SIGDA International Symposium on Field-Programmable Gate Arrays, ser. FPGA ′21. New York, NY, USA: Association for Computing Machinery, 2021, p. 81-92.

### SUMMARY

The technical problem to be solved by the present disclosure is: the scalability of existing multi-die FPGA and its supporting EDA tools cannot meet the scale growth of circuit designs. For example, the most advanced EDA tool on the most advanced commercial FPGA Xilinx U250 can only complete a 13×16 scale layout at 316 MHz for convolutional neural networks.

In order to solve the above-mentioned technical problem, one technical solution of the present disclosure is to provide a layout method for a scalable multi-die network-on-chip FPGA architecture, where when a structure parameter is (), the FPGA architecture is a single die; when the structure parameter is (m), m is a positive integer, the FPGA architecture is that m single crystal dies are connected to one NoC router via an NoC, and the NoC router is referred to as a central router of the FPGA architecture; when the structure parameters are (m₁, m₂), m₁ and m₂ are positive integers, and the FPGA architecture is that central routers of the m₂ (m₁) structure are connected to one NoC router via an NoC, and the NoC router is referred to as a central router of the FPGA architecture; when the structure parameter is (m₁, . . . , mₙ), m₁, . . . , mₙ are positive integers, the FPGA architecture is that central routers of mₙ (m₁, . . . , mₙ₋₁) structures are connected to one NoC router via an NoC, the NoC router is referred to as a central router of the FPGA architecture, and the (m₁, . . . , mₙ₋₁) structures are referred to as a secondary substructure;

the layout of the FPGA architecture includes an integer linear programming problem and a hierarchical recursive layout algorithm based on the integer linear programming problem, where:

the integer linear programming problem includes the following steps:

step 1: taking the FPGA architecture model as a graph G_{FPGA}, G_{FPGA}=(Tₘ^{l}, \tilde{B}, a(T_{*}⁰)),\tilde{ }where Tₘ^{l} is an architecture topology, [symbol] is a link bandwidth of each layer of NoC, and a(T_{*}⁰) is resource capacity of each die; and taking the dataflow design as graph G_{design}, G_{design}=(V, E, a(V), S(E), D(E), w(E)), where V is a dataflow module, E is a dataflow queue, a(V) is an area of the dataflow module, S(E) is a start point of the dataflow queue, D(E) is an end point of the dataflow queue, and w(E) is a bitwidth of the dataflow queue;

step 2: taking φ:V→T_{*}⁰ as a target layout, T_{*}⁰ represents the die, and an objective function dominated by a vertex is as follows:

$${arg min}_{φ : V \to {T}_{*}^{0}} {\sum }_{e ∈ E} w ( e ) {d}_{m} ( φ ( S ( e ) ) , φ ( D ( e ) ) )$$

where w(e) represents a dataflow queue bitwidth, dₘ(⋅, ⋅) represents a distance metric, S(e)represents a queue source module, φ(S(e)) represents a die corresponding to the queue source module, D(e) represents a queue drain module, and φ(D(e)) represents a die corresponding to the queue drain module;

step 3: encoding a linearized vertex space using a one-hot code, accordingly a linearized linear transformation φ of Φ, so that there is a linearized objective function as the objective function of the integer linear programming problem, as shown in the following formula:

$${arg min}_{Φ} {\sum }_{e ∈ E} {w}^{T} e \cdot {d}_{m} ( Φ Se , Φ De )$$

where w^{T} e represents a linear form of a dataflow queue bit-width, Se represents a linear form of a queue source module, ΦSe represents a linear form of a die corresponding to the queue source module, De represents a linear form of a queue drain module, and ΦDe represents a linear form of a die corresponding to the queue drain module;

step 4: laying out each dataflow module on exactly 1 die, formalizing same as a constraint as shown in the following formula:

$${\sum }_{x ∈ {T}_{*}^{0}} {Φ}_{xv} = 1 , ∀ v ∈ V$$

where x represents a target die, v represents a dataflow module to be laid out, and Φₓᵥ represents a layout decision variable which is 1 if the dataflow module x is allocated to a die v, otherwise 0;

step 5: making the total resource of the dataflow module on the same die not exceed the total resource of the die; and formalizing same as a constraint represented by the formula:

$${\sum }_{v ∈ V} a ( v ) {Φ}_{xv} \leq a ( x ) , ∀ v ∈ V , ∀ x ∈ {T}_{*}^{0}$$

where a(v) represents resource occupation of the dataflow module v, and a(x) represents resource capacity of the die x; and

step 6: providing, by a user, a manual layout, and formalizing same as a constraint as shown in the following formula:

Φv=φ_{M}(v), ∀v ϵ V_{M}

where φ_{M}(v) represents a manual allocation of a die corresponding to a dataflow module by the user, and V_{M} represents a dataflow module for manually allocating a die by a design user;

the hierarchical recursive layout algorithm includes the following steps:

step a: summarizing the layout results of the dataflow module on the substructure of the FPGA topology Tₘ^{l} as V_{m,x}ⁿ, as shown in the following two formulae:

V_{m,x}ⁿ=V_{m,()}^{l} [symbol] V (n=l)

V_{m∂,x}ⁿ [symbol] {v ϵ V_{m,∂x}ⁿ⁺¹|φ_{m∂,x}ⁿ⁺¹ (v)=T_{m∂, x}ⁿ} (n≠l)

where V_{m,()}^{l} represents a top substructure, V_{m,x}ⁿ represents the n level substructure of which the structure parameter is m and the position is x, m∂ represents a tuple m excluding the tail item, and ∂x represents a tuple x excluding the first item;

step b: defining a recursive layout operator ϕ:

ϕ (T_{m,x}ⁿ, v) [symbol] ϕ (φ_{m,x}ⁿ(v), v)

= . . . [symbol] ϕ (T_{y}⁰, v), ∃T_{y}⁰ ϵ T_{*}⁰, ∀v ϵ V

where ϕ (T_{m,x}ⁿ, v) represents a recursive layout of a module v calculated from the n level substructure, φ_{m,x}ⁿ (v) represents the secondary layout of the module v on the n level substructure, and T_{y}⁰ represents a crystal die with position y;

with φ(v) [symbol] ϕ(φ_{m,x}ⁿ (v), v), ∀v ϵ V, the solution of the original layout problem to φ is decomposed into the solution of the layout φ_{m,x}ⁿ:V_{m,x}ⁿ→T_{m,x}ⁿ on the substructure;

step c: representing the objective function on the substructure instead using edge dominance as shown in the following formula:

$${arg min}_{{Φ}_{m , x}^{n}} {\sum }_{e ∈ {E}_{m , x}^{n}} {w}^{T} e \cdot {d}^{T} Ξ e$$

where Φ_{m,x}ⁿ represents a layout to be solved on the n substructure of which the structure parameter is m and the position is x, E_{m,x}ⁿ represents a dataflow queue allocated to the n substructure of structure parameter m and position x, d represents a distance metric of the network-on-chip link, and Ξe represents the network-on-chip link corresponding to the dataflow queue on the n substructure; and

step d: establishing a constraint based on the following conditions when performing a layout:

the dataflow module is allocated to a secondary substructure on the substructure;

the dataflow queue is allocated to exactly one link of the current substructure central router and the secondary substructure central router on the substructure;

the allocation of the dataflow module is consistent with the allocation of the dataflow queue;

for the resource estimation of the i substructure, a congestion factor ρᵢ is introduced as the modification of Σ_{vϵV} a(v)Φₓᵥ≤a(x), ∀v ϵ V, ∀x ϵ T_{*}⁰, as shown in the following formula:

$${\sum }_{v ∈ {V}_{m , x}^{n}} a ( v ) {( {Φ}_{m , x}^{n} )}_{xv} \leq {ρ}_{n} a ( x ) , ∀ x ∈ {T}_{m , {x}^{′}}^{n} ∀ a ∈ A$$

where A represents a resource type.

The dataflow module bit-width allocated to the link shall not exceed the link bandwidth;

the layout on the substructure coincides with the user's manual layout.

For a 0 level substructure, the structure parameter is (), and the FPGA architecture is represented by the following formula:

$${T}_{m , X}^{n} = {T}_{( ) , X}^{0} {=}^{△} {T}_{X}^{0} = {\sum }_{i = 1}^{n} {{\prod }_{j = 1}}^{i - 1} {m}_{j} {x}_{i}$$

where T_{m,X}ⁿ represents the n substructure of which the structure parameter is m and the position is X, T_{(),X}⁰ represents the 0 substructure of which the structure parameter is () and the position is X, T_{X}⁰ represents a die of which the position is X, mⱼ represents an item j of a total structure parameter, xᵢ represents an item i of a tuple X.

For the n substructure, when the structure parameter is (m₁, . . . , mₙ), the FPGA architecture is represented as follows:

T_{m,X}ⁿ [symbol] {T_{m∂,(x,X)}ⁿ⁻¹|0≤x<mₙ₋₁, x ϵ [symbol] ⁺}

where T_{m∂,(x,X)}ⁿ⁻¹ represents the n−1 substructure of which the structure parameter is m∂ and position is (x, X)), and x represents the relative position of the n−1 substructure in the current n substructure.

Another technical solution of the present disclosure is to provide an application of the above-mentioned layout method for a scalable multi-die network-on-chip FPGA architecture, which is used in the design of a multi-die FPGA to improve the scalability of the FPGA architecture and facilitate the scalable implementation of a matched EDA tool.

The present disclosure discloses a scalable multi-die FPGA architecture based on network-on-chip and a corresponding hierarchical recursive layout algorithm, aiming to directly map a register transfer level dataflow design generated by existing high-level synthesis onto the provided interconnection architecture. The method disclosed in the present disclosure can exploit the potential for hierarchical topology and make more efficient use of dedicated interconnection resources, such as cross-die nets, network-on-chips, and high-speed transceivers. Compared with the prior art solutions, the present disclosure has the following innovations:
1) A network-on-chip based multi-die FPGA with hierarchical topology, which can improve the scalability of FPGA scale relative to the number of dies, and is more friendly to the efficient implementation of the layout algorithm.
2) This paper presents an integer linear programming problem representation for layout problems on interconnected architectures. Compared with the traditional layout problem on Cartesian grids, the latter distance metric is only a 11 norm of the vertex coordinate difference, while the former is defined on the edges of the load dataflow on the novel distance metric of the network-on-chip hierarchical interconnection architecture provided in the present disclosure and involves a complex combination of integer linear programming primitives represented by cascaded conditional branches. Also introduced is a consistency constraint of vertex and edge layout results in the dataflow graph.
3) A novel recursive method solves the above integer linear programming problem. Using the hierarchical nature of the provided architecture, the method disclosed in the present disclosure divides the original problem into separate sub-problems on the sub-architecture. This not only reduces the overall complexity of the problem, but also introduces many parallelization opportunities.

### BRIEF DESCRIPTION OF THE DRAWINGS

FIG. 1 shows the structure of the architecture when the structure parameter is (8, 8) according to the present disclosure.

FIG. 2 shows a flow chart of a hierarchical layout algorithm according to the present disclosure;

FIG. 3 shows a specific implementation of the algorithm according to the present disclosure.

### DETAILED DESCRIPTION OF THE EMBODIMENTS

The present disclosure is further illustrated by the following embodiments. These embodiments are illustrative only and are not intended to limit the scope of the present disclosure. Further, a person skilled in the art, upon reading the teachings of the present disclosure, may make various changes and modifications to the present disclosure, and that such equivalents are intended to fall within the scope of the appended claims.

For a multi-die FPGA based on a network-on-chip, we recursively define an m tree topology thereon, where m={mᵢ}ᵢ₌₁^{l} is the total structure parameter. For the basic case of l=1, the topology is that mₗ=m₁ dies are connected to a central router, and the router is called a level 1 router; for l>1, the topology is that level l−1 routers of mₗ {mᵢ}ᵢ₌₁^{l-1} trees are connected to a central router, and the router is called a level l central router.

The architecture of the scalable multi-die network-on-chip FPGA provided in the present disclosure is as follows:

when the structure parameter is (), the referred FPGA architecture substructure is a single die as shown in the following formula:

$${T}_{m , X}^{n} = {T}_{( ) , X}^{0} {=}^{△} {T}_{X}^{0} = {\sum }_{i = 1}^{n} {{\prod }_{j = 1}}^{i - 1} {m}_{j} {x}_{i}$$

where T_{m,X}ⁿ represents the n substructure of which the structure parameter is m and the position is X, T_{(),X}⁰ represents the 0 substructure of which the structure parameter is () and the position is X, T_{X}⁰ represents a die of which the position is X, mⱼ represents an item j of a total structure parameter, xᵢ represents an item i of a tuple X.

When the structure parameter is (m), where m is a positive integer, the FPGA architecture referred to is that m single dies are connected to one NoC router via an NoC (referred to as the central router of the structure).

When the structure parameters are (m₁,m₂)(where m₁ and m₂ are positive integers), the referred FPGA architecture is that the central routers of m₂ (m₁) structures are connected to one NoC router via an NoC, and the NoC router is referred to as the central router of the FPGA architecture.

When the structure parameters are (m₁, . . . , mₙ) (where m₁, . . . , mₙ are positive integers), the referred FPGA architecture is that the central routers of mₙ (m₁, . . . , mₙ₋₁)structures (referred to as a secondary substructure) are connected to one NoC router via an NoC, and the NoC router is referred to as the central router of the FPGA architecture, as shown in the formula below:

T_{m,X}ⁿ [symbol] {_{m∂,(x,X)}ⁿ⁻¹|0≤x<mₙ₋₁, x ϵ [symbol] ⁺}

where T_{m∂,(x,X)}ⁿ⁻¹ represents the n−1 substructure of which the structure parameter is m∂ and position (x, X)), and x represents the relative position of the n−1 substructure in the current n substructure.

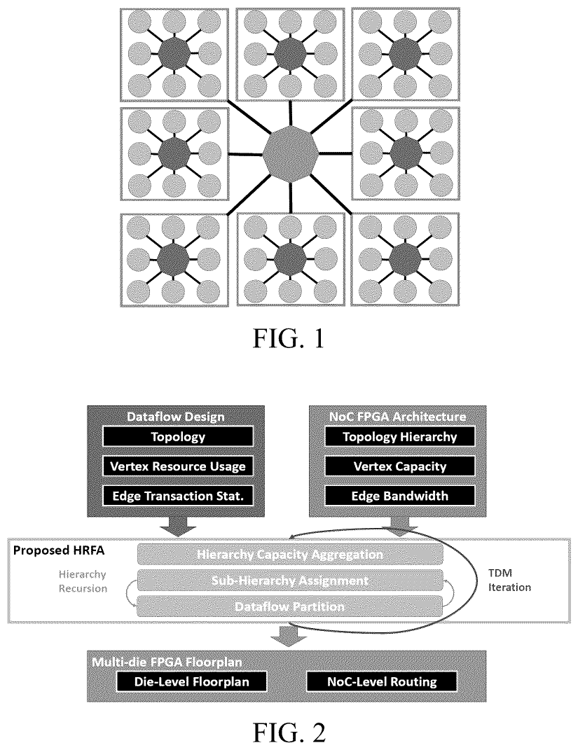

The FPGA architecture when the structure parameter is (8, 8) is shown in FIG. 1.

The distance metric on the provided architecture is as follows:

$${d}_{m} ( {T}_{{x}_{1}}^{0} , {T}_{{x}_{2}}^{0} ) = {d}_{m} ( {x}_{1} , {x}_{2} ) {=}^{△} {max}_{i = 1 , 2 , … , l} 2 i {I}_{[ {( {x}_{1} )}_{i} \neq {( {x}_{2} )}_{i} ]}$$

where Tₓ_{₁}⁰ represents a die at position x₁, Tₓ_{₂}⁰ represents a die at position x₂, x₁ represents the 1 die of the die pair with a distance to be solved, x₂ represents the 2 die of the die pair with a distance to be solved, (x₁)ᵢ represents the i item of the tuple x₁, (x₂)ᵢ represents the i item of the tuple x₂, I_{[(x}_{₁}₎_{ᵢ}_{≠(x}_{₂}₎_{ᵢ}_{]} represents an indicator variable with a value of 1 when (x₁)ᵢ≠(x₂)ᵢ, otherwise 0.

The resource calculation on the provided architecture substructure is as follows:

$$\{ \begin{matrix}a ( {T}_{m , X}^{n} ) {=}^{△} {\sum }_{{T}^{n - 1} ∈ {T}_{m , X}^{n}} a ( {T}^{n - 1} ) ( n \geq 1 ) \\ a ( {T}_{m , X}^{n} ) = a ( {T}_{X}^{0} ) {=}^{△} a ( X ) ( n = 0 )\end{matrix}$$

where a(T_{m,X}ⁿ) represents the resource capacity of the n substructure of which the structure parameter is m and the position is x, Tⁿ⁻¹ represents the n−1 substructure in the current n substructure, T_{X}⁰ represents the die at a position X, and a(X) represents the resource capacity of the die X.

When the NoC supports time division multiplexing, a time division multiplexing factor is taken as k_{TDM}, a i level NoC link bandwidth is taken as Bᵢ, a nominal operating frequency of the NoC is taken as ƒ_{NoC}, and the designed nominal operating frequency is taken as ƒₒₚ, the equivalent bandwidth of the NoC link is taken as \tilde{B}ᵢ=Bᵢ/k_{TDM}, and the designed equivalent operating frequency is taken as

$${\tilde{f}}_{op} = min \{ \frac{{f}_{op}}{{k}_{TDM}} , {f}_{NoC} \} .$$

Then the integer linear programming problem of the proposed layout problem is represented as follows:

Step 1: taking the FPGA architecture model as a graph G_{FPGA}, where G_{FPGA}=(Tₘ^{l}, \tilde{B}, a(T_{*}⁰)), Tₘ^{l} is architecture topology, [symbol] is a link bandwidth of each layer of NoC, and a(T_{*}⁰) is the resource capacity of each die; and taking the dataflow design as graph G_{design}, where G_{design}=(V, E, a(V), S(E), D(E), w(E)), V is a dataflow module, E is a dataflow queue, a(V) is an area of the dataflow module, S(E) is a start point of the dataflow queue, D(E) is an end point of the dataflow queue, and w(E) is a bitwidth of the dataflow queue.

Step 2: taking φ: V→T_{*}⁰ as a target layout, T_{*}⁰ represents a set of all dies, and the objective function dominated by the vertex is as follows:

$${arg min}_{φ : V \to {T}_{*}^{0}} {\sum }_{e ∈ E} w ( e ) {d}_{m} ( φ ( S ( e ) ) , φ ( D ( e ) ) )$$

where w(e) represents a dataflow queue bitwidth, dₘ(⋅, ⋅) represents a distance metric, S(e) represents a source module of the dataflow queue, φ(S(e)) represents the die corresponding to the source module of the dataflow queue, D(e) represents a drain module of the dataflow queue, and φ(D(e)) represents the die corresponding to the drain module of the dataflow queue.

Step 3: encoding a linearized vertex space using a one-hot code, accordingly a linearized linear transformation Φ of φ, so that there is a linearized objective function as the objective function of the integer linear programming problem, as shown in the following formula:

$${arg min}_{Φ} {\sum }_{e ∈ E} {w}^{T} e \cdot {d}_{m} ( Φ Se , Φ De )$$

where w^{T}e represents a linear form of a dataflow queue bitwidth, Se represents a linear form of a source module of the dataflow queue, Φ Se represents a linear form of a die corresponding to the source module of the dataflow queue, De represents a linear form of a drain module of the dataflow queue, and ΦD e represents a linear form of a die corresponding to the drain module of the dataflow queue.

Step 4: laying out each dataflow module on exactly 1 die, formalizing same as a constraint as shown in the following formula:

$${\sum }_{x ∈ {T}_{*}^{0}} {Φ}_{xv} = 1 , ∀ v ∈ V$$

where x represents a target die, v represents a dataflow module to be laid out, and Φₓᵥ represents a layout decision variable which is 1 if the dataflow module x is allocated to a die v, otherwise 0.

Step 5: making the total resource of the dataflow module on the same die not exceed the total resource of the die; and formalizing same as a constraint represented by the formula:

$${\sum }_{v ∈ V} a ( v ) {Φ}_{xv} \leq a ( x ) , ∀ v ∈ V , ∀ x ∈ {T}_{*}^{0}$$

where a(v) represents resource occupation of the dataflow module v, and a(x) represents resource capacity of the die x.

Step 6: providing, by a user, a manual layout, and formalizing same as a constraint as shown in the following formula:

Φv=φ_{M}(v), ∀v ϵ V_{M}

where φ_{M}(v) represents a manual allocation of a die corresponding to a dataflow module by the user, and V_{M} represents a dataflow module for manually allocating a die by a design user.

The provided hierarchical recursive layout algorithm is represented as follows:

Step 1: summarizing the layout results of the dataflow module on the substructure of the FPGA topology Tₘ^{l} as V_{m,x}ⁿ,

as shown in the following two formulae:

V_{m,x}ⁿ=V_{m,()}^{l} [symbol] V (n=l)

V_{m∂,x}ⁿ [symbol] {v ϵ V_{m,∂x}ⁿ⁺¹|φ_{m,∂x}ⁿ⁺¹(v)=T_{m∂, x}ⁿ} (n≠l)

where V_{m,()}^{l} represents a top substructure, V_{m,x}ⁿ represents the n level substructure of which the structure parameter is m and the position is x, m∂ represents a tuple m excluding the tail item, and ∂x represents a tuple x excluding the first item;

Step 2:

defining a recursive layout operator ϕ:

ϕ(T_{m,x}ⁿ, v) [symbol] ϕ(ϕ_{m,x}ⁿ(v), v)

= . . . [symbol] ϕ(T_{y}⁰, v), ∃T_{y}⁰ ϵ T_{*}⁰, ∀v ϵ V

where ϕ(T_{m,x}ⁿ, v) represents a recursive layout of a module v calculated from the n level substructure, φ_{m,x}ⁿ(v) represents the secondary layout of the module v on the n level substructure, and T_{y}⁰ represents a crystal die with position y.

With φ(v) [symbol] ϕ(φ_{m,x}ⁿ(v), v), ∀v ϵ V, the solution of the original layout problem to φ is decomposed into the solution of the layout φ_{m,x}ⁿ:V_{m,x}ⁿ→T_{m,x}ⁿ on the substructure.

Step 3: representing the objective function on the substructure instead using edge dominance as shown in the following formula:

$${arg min}_{{Φ}_{m , x}^{n}} {\sum }_{e ∈ {E}_{m , x}^{n}} {w}^{T} e \cdot {d}^{T} Ξ e$$

where Φ_{m,x}ⁿ represents a layout to be solved on the n substructure of which the structure parameter is m and the position is x, x E_{m,x}ⁿ represents a dataflow queue allocated to the n substructure of structure parameter m and position x, d represents a distance metric of the network-on-chip link, and Ξe represents the network-on-chip link corresponding to the dataflow queue on the n substructure.

Step 4: allocating the dataflow module exactly to a secondary substructure on the substructure, and formalizing same as a constraint as shown in the following formula:

$${\sum }_{x ∈ {T}_{m , x}^{n}} {( {Φ}_{m , x}^{n} )}_{xv} = 1 , ∀ v ∈ {V}_{m , x}^{n}$$

where (Φ_{m,x}ⁿ)ₓᵥ indicates whether the dataflow module v is allocated to the x secondary substructure on the n substructure of which the structure parameter is m and the position is x.

Step 5: calculating that a flow queue should be allocated to exactly one link of the current substructure central router and the secondary substructure central router on the substructure, and formalizing same as the constraint as shown in the following formula:

$${\sum }_{η ∈ {E}_{T}} {Ξ}_{η e} = 1 , ∀ e ∈ {E}_{m , x}^{n}$$

where Ξ_{ηe} represents whether or not the dataflow queue e is allocated to a layout decision variable of link η, η represents the network-on-chip link between the secondary sub-nodes in the current n^{th} substructure, and E_{T} represents the totality of the network-on-chip links between the secondary sub-nodes in the current n^{th} substructure.

Step 6: calculating that the flow module allocation should be consistent with calculating the flow queue allocation, and formalizing same as the constraint as shown in the following formula:

Φ_{m,x}ⁿS_{m,x}ⁿ=S_{T}Ξ

Φ_{m,x}ⁿD_{m,x}ⁿ=D_{T}Ξ

where S_{m,x}ⁿ represents a source module mapping laid out to a data queue on an n substructure of which the structure parameter is m and the position is x, D_{m,x}ⁿ represents a drain module mapping laid out to a data queue on a n substructure of which the structure parameter is m and the position is x, S_{T}Ξ represents a source substructure of a network-on-chip link between secondary substructures within the current n th substructure, and D_{T}Ξ represents a drain substructure of a network-on-chip link between secondary substructures within the current n^{th} substructure.

Step 7: introducing a congestion factor ρᵢ as the modification of Σ_{vϵV}a(v)Φₓᵥ≤a(x), ∀v ϵ V, ∀x ϵ T_{*}⁰ for the resource estimation of the i substructure, as shown in the following formula:

$${\sum }_{v ∈ {V}_{m , x}^{n}} a ( v ) {( {Φ}_{m , x}^{n} )}_{xv} \leq {ρ}_{n} a ( x ) , ∀ x ∈ {T}_{m , {x}^{′}}^{n} ∀ a ∈ A$$

where A represents a resource type.

Step 8: making the bit-width of the dataflow module allocated to the link not exceed the link bandwidth, and formalizing same as the constraint as shown in the following formula:

$$( 1 - {δ}_{η} ) {\sum }_{e ∈ {E}_{m , x}^{n}} w ( e ) {Ξ}_{η e} \leq {\tilde{B}}_{n}$$

where δ represents whether the source and drain of a link η are of the same substructure, w(e) represents a dataflow queue bitwidth, and Ξ_{ηe} represents whether the dataflow queue e is laid out in the layout decision variable of the link η.

Step 9: making the layout on the substructure be consistent with the user's manual layout, and formalizing same as the constraint as shown in the following formula:

φ_{m,x}ⁿ(v)=T_{m∂,∂}_{ⁿ}_{/φ}_{_{M}}_{(v)/}, ∀v ϵV_{m,x}ⁿ∩V_{M}

where m∂ represents a tuple m excluding the tail term, ∂ⁿ[φ_{M}(v)] represents a relative position of the user manual layout die in the n substructure, T_{m∂,∂}_{[φ}_{_{M}}_{(v)]} represents the corresponding secondary substructure of the user manual layout die in the n substructure, and V_{M} represents the dataflow module related to the user's manual layout.

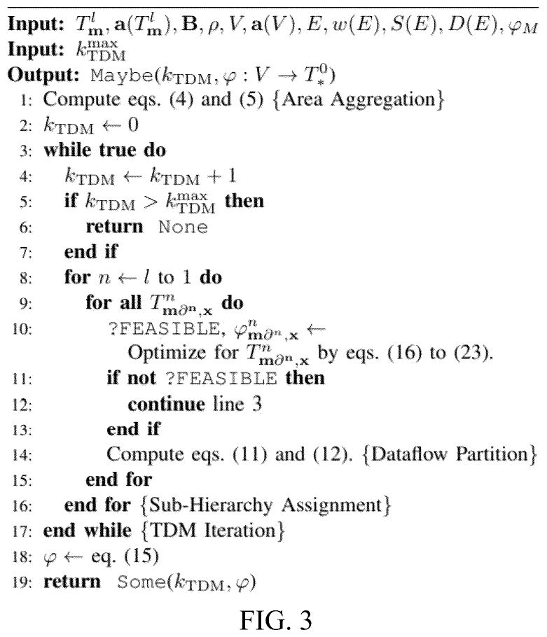

The specific implementation of the algorithm provided in the present disclosure is shown in FIG. 3, which includes the following steps:

for the proposed layout problem, starting with k_{TDM}=0, a loop attempt layout is performed as shown in row 2 to row 3 of FIG. 3.

First, k_{TDM} is subjected to auto-increment, as shown in row 4 of FIG. 3, and if k_{TDM} exceeds the user's given upper limit, then no solution is reported, as shown in lines 5 through 7 of FIG. 3.

A level-by-level substructure recursive attempt is as shown in rows 8 and 9 in FIG. 3. The attempted content is a substructure layout as shown in row 10 of FIG. 3. If no solution is reported by any hierarchy or any substructure, the round is discarded and the next round is attempted, as shown in rows 11 through 13 in FIG. 3. For a successful attempt, the values of V_{m,x}ⁿ=V_{m,()}^{l} [symbol] V and V_{m∂,x}ⁿ [symbol] {v ϵ V_{m,∂x}ⁿ⁺¹/φ_{m,∂x}ⁿ⁺¹(v)=T_{m∂,x}ⁿ} at the current substructure are counted. As shown in row 14 of FIG. 3, V_{m,∂x}ⁿ⁺¹ represents an upper-level substructure, T_{m∂,x}ⁿ represents the current substructure, and φ_{m,∂x}ⁿ⁺¹(v) represents a layout result on the upper-level substructure.

If a feasible solution is found before k_{TDM} exceeds the upper limit, the overall layout result is calculated according to φ(v) [symbol] Φ(φ_{m,x}ⁿ(v), v), ∀v ϵ V, as shown in row 18 in FIG. 3, and the layout result φ under the time division multiplexing factor k_{TDM} is reported, as shown in row 19 in FIG. 3.

The provided scalable architecture part of the present disclosure can be applied to the design of a new multi-die FPGA to improve the scalability of the FPGA architecture and facilitate the scalable implementation of a matched EDA tool. The hierarchical layout algorithm provided in the present disclosure can be scalably applied to the EDA tools required by the new multi-die FPGA to greatly increase the achievable design scale while reducing the running time of the algorithm without reducing the design performance.

What is claimed is:

1. A layout method for a scalable multi-die network-on-chip field-programmable gate array (FPGA) architecture, wherein when a structure parameter is (), the FPGA architecture is a single die; when the structure parameter is (m), m is a positive integer, the FPGA architecture is that m single crystal dies are connected to one NoC router via an NoC, and the NoC router is referred to as a central router of the FPGA architecture; when the structure parameters are (m₁, m₂), m₁ and m₂ are positive integers, and the FPGA architecture is that central routers of the m 2 (m 7) structure are connected to one NoC router via an NoC, and the NoC router is referred to as a central router of the FPGA architecture; when the structure parameter is (m₁, . . . , mₙ), m, . . . , mₙ are positive integers, the FPGA architecture is that central routers of mₙ (m₁, . . . , mₙ₋₁) structures are connected to one NoC router via an NoC, the NoC router is referred to as a central router of the FPGA architecture, and the (m₁, . . . , mₙ₋₁) structures are referred to as a secondary substructure;
a layout of the FPGA architecture comprises an integer linear programming problem and a hierarchical recursive layout algorithm based on the integer linear programming problem, wherein:
the integer linear programming problem comprises the following steps:
step 1: taking the FPGA architecture model as a graph G_{FPGA}, G_{FPGA}=(Tₘ^{l}, \tilde{B}, a(T_{*}⁰)),\tilde{ }wherein Tₘ^{l} is an architecture topology, [symbol] is a link bandwidth of each layer of NoC, and a(T_{*}⁰) is resource capacity of each die; and taking a dataflow design as graph G_{design}, G_{design}=(V, E, a(V), S(E), D(E), w(E)) , wherein V is a dataflow module, E is a dataflow queue, a(V) is an area of the dataflow module, S(E) is a start point of the dataflow queue, D(E) is an end point of the dataflow queue, and w(E) is a bitwidth of the dataflow queue;
step 2: taking φ:V→T_{*}⁰ as a target layout, T_{*}⁰ represents a set of all dies, and an objective function dominated by a vertex is as follows:
$${arg min}_{φ : V \to {T}_{*}^{0}} {\sum }_{e ∈ E} w ( e ) {d}_{m} ( φ ( S ( e ) ) , φ ( D ( e ) ) )$$
wherein w(e) represents a dataflow queue bitwidth, dₘ(⋅, ⋅) represents a distance metric, S(e) represents a source module of the dataflow queue, φ(S(e)) represents a die corresponding to the source module of the dataflow queue, D(e) represents a drain module of the dataflow queue, and φ(D(e)) represents a die corresponding to the drain module of the dataflow queue;
step 3: encoding a linearized vertex space using a one-hot code, accordingly a linearized linear transformation φ of Φ, so that there is a linearized objective function as the objective function of the integer linear programming problem, as shown in the following formula:
$${arg min}_{Φ} {\sum }_{e ∈ E} {w}^{T} e \cdot {d}_{m} ( Φ Se , Φ De )$$
wherein W^{T}e represents a linear form of the dataflow queue bitwidth, Se represents a linear form of a queue source module, ΦSe represents a linear form of a die corresponding to the queue source module, De represents a linear form of a queue drain module, and ΦDe represents a linear form of a die corresponding to the queue drain module;
step 4: laying out each dataflow module on exactly 1 die, formalizing same as a constraint as shown in the following formula:
$${\sum }_{x ∈ {T}_{*}^{0}} {Φ}_{xv} = 1 , ∀ v ∈ V$$
wherein x represents a target die, v represents a dataflow module to be laid out, and Φₓᵥ represents a layout decision variable which is 1 if the dataflow module x is allocated to a die v, otherwise 0;
step 5: making a total resource of the dataflow module on the same die not exceed a total resource of the die; and formalizing same as a constraint represented by the following formula:
$${\sum }_{v ∈ V} a ( v ) {Φ}_{xv} \leq a ( x ) , ∀ v ∈ V , ∀ x ∈ {T}_{*}^{0}$$
wherein a(v) represents resource occupation of the dataflow module V, and a(x) represents resource capacity of the die x; and
step 6: providing, by a user, a manual layout, and formalizing same as a constraint as shown in the following formula:
Φv=φ_{M}(v), ∀v ϵ V_{M}
wherein φ_{M}(v) represents a manual allocation of a die corresponding to a dataflow module by the user, and V_{M} represents a dataflow module for manually allocating a die by a design user;
the hierarchical recursive layout algorithm comprises the following steps:
step a: summarizing layout results of the dataflow module on the substructure of the FPGA topology Tₘ^{l} as V_{m,x}ⁿ, as shown in the following two formulae:
V_{m,x}ⁿ=V_{m,()}^{l} [symbol] V (n=l)
V_{m∂,x}ⁿ [symbol] {v ϵ V_{m,∂x}ⁿ⁺¹|φ_{m,∂x}ⁿ⁺¹(v)=T_{m∂, x}ⁿ} (n≠l)
wherein V_{m,()}^{l} represents a top substructure, V_{m,x}ⁿ represents an n level substructure of which a structure parameter is m and a position is x, m∂ represents a tuple m excluding a tail item, and ∂x represents a tuple x excluding a first item;
step b: defining a recursive layout operator ϕ:
ϕ(T_{m,x}ⁿ, v) [symbol] ϕ(φ_{m,x}ⁿ(v), v)
= . . . [symbol] ϕ(T_{y}⁰, v), ∃T_{y}⁰ ϵ T_{*}⁰, ∀v ϵ V
wherein ϕ(T_{m,x}ⁿ, v) represents a recursive layout of a module v calculated from the n level substructure, φ_{m,x}ⁿ(v) represents a secondary layout of the module V on the n level substructure, and T_{y}⁰ represents a crystal die with position y; with φ(v) [symbol] Φ(φ_{m,x}ⁿ(v), v) , ∀v ϵ V, a solution of an original layout problem to φ is decomposed into a solution of a layout φ_{m,x}ⁿ:V_{m,x}ⁿ→T_{m,x}ⁿ on the substructure;
step c: representing the objective function on the substructure instead using edge dominance as shown in the following formula:
$${arg min}_{{Φ}_{m , x}^{n}} {\sum }_{e ∈ {E}_{m , x}^{n}} {w}^{T} e \cdot {d}^{T} Ξ e$$
wherein Φ_{m,x}ⁿ represents a layout to be solved on the n substructure of which the structure parameter is m and the position is x , E_{m,x}ⁿ represents a dataflow queue allocated to the n substructure of structure parameter m and position x, d represents a distance metric of the network-on-chip link, and Ξe represents the network-on-chip link corresponding to the dataflow queue on the n substructure; and
step d: establishing a constraint based on the following conditions when performing a layout:
a dataflow module is allocated to a secondary substructure on the substructure;
a dataflow queue is allocated to exactly one link of a current substructure central router and a secondary substructure central router on the substructure;
the allocation of the dataflow module is consistent with the allocation of the dataflow queue;
for a resource estimation of an i substructure, a congestion factor p i is introduced as a modification of Σ_{vϵV}a(v)Φₓᵥ≤a(x), ∀v ϵ V, ∀x ϵ T_{*}⁰, as shown in the following formula:
$${\sum }_{v ∈ {V}_{m , x}^{n}} a ( v ) {( {Φ}_{m , x}^{n} )}_{xv} \leq {ρ}_{n} a ( x ) , ∀ x ∈ {T}_{m , {x}^{′}}^{n} ∀ a ∈ A$$
wherein A represents a resource type;
a dataflow module bit-width allocated to the link shall not exceed the link bandwidth;
the layout on the substructure coincides with the user's manual layout.

2. The layout method for the scalable multi-die network-on-chip FPGA architecture according to claim 1, wherein when the structure parameter is (), the FPGA architecture is represented by the following formula:
$${T}_{m , X}^{n} = {T}_{( ) , X}^{0} {=}^{△} {T}_{X}^{0} = {\sum }_{i = 1}^{n} {\prod }_{j = 1}^{i - 1} {m}_{j} {x}_{i}$$
wherein x T_{m,x}ⁿ represents the n substructure of which the structure parameter is m and the position is X, T_{(),X}⁰ represents a 0 substructure of which the structure parameter is () and the position is X, T_{X}⁰ represents a die of which the position is X, mⱼ represents an item j of a total structure parameter, and xᵢ represents an item i of a tuple X.

3. The layout method for the scalable multi-die network-on-chip FPGA architecture according to claim 1, wherein when the structure parameter is (m₁, . . . , mₙ), the FPGA architecture is represented by the following formula:
T_{m,X}ⁿ [symbol] {T_{m∂,(x,X)}ⁿ⁻¹|0≤x<mₙ₋₁, i ϵ [symbol] ⁺}
wherein T_{m∂,(x,X)}ⁿ⁻¹ represents an n−1 substructure of which the structure parameter is m∂ and the position (x, X)), and x represents a relative position of the n−1 substructure in the current n substructure.

4. A design method of a multi-die FPGA, comprising: using the layout method for the scalable multi-die network-on-chip FPGA architecture according to claim 1 to improve a scalability of the FPGA architecture and facilitate a scalable implementation of a matched electronic design automation (EDA) tool.
